(19) United States
(12) Patent Application Publication
(10) Pub. No.: US 2025/0046496 A1
(43) Pub. Date: Feb. 6, 2025

(54) FLEXIBLE SUPERCONDUCTING MICRO-COAXIAL CABLE AND ASSOCIATED METHODS

(71) Applicant: Timothy A Johnson, Bozeman, MT (US)

(72) Inventor: Timothy A Johnson, Bozeman, MT (US)

(21) Appl. No.: 18/364,427

(22) Filed: Aug. 2, 2023

(51) Int. Cl. H01B 12/08; H10N 60/01; H10N 60/85

(52) U.S. Cl. CPC H01B 12/08; H10N 60/0156; H10N 60/0184; H10N 60/85

(57) ABSTRACT

The flexible superconducting micro-coaxial cable is designed for use in quantum computing systems. The micro-coaxial cable includes an inner conductor made of a first superconductive material, surrounded by a dielectric layer. Circumferentially surrounding the dielectric layer is a braided outer conductor, made of a second superconductive material, providing more than 90% coverage. The first and second superconductive materials can be either type-I superconductors, such as Aluminum (Al), Lead (Pb), Titanium (Ti), Indium (In), and Tin (Sn), or type-II superconductors, including magnesium diboride (MgB2), niobium-titanium (NbTi), niobium-tin (Nb3Sn), and niobium-germanium (Nb3Ge).

### FIELD OF THE INVENTION

The present invention relates to coaxial cables, and more specifically to a superconducting micro-coaxial cable and associated methods.

### BACKGROUND

The past decade has seen significant growth in research and applications for quantum sensing, quantum communication, and quantum computing. Quantum computers are being built by many companies and employ a variety of engineering approaches. Quantum computers use “qubits” to perform computation, which is the quantum computer equivalent of a classical computer bit. The number of qubits being employed in each quantum computer will increase substantially in the coming years to give quantum computers the ability to execute faster, more complex computations than a classic computer could ever achieve, something known as “quantum supremacy”. The qubit number in each quantum computer is expected to grow from a few hundred (currently) to a million or more in the next decade.

For quantum computers to operate they must first be cooled down to temperatures near absolute zero (below 4 Kelvin) using a dilution refrigerator or other type of cryostat. The low temperature minimizes the amount of thermal energy in and around the quantum computer and the low temperature must be maintained for the quantum computer to function properly.

Numerous coaxial cables are connected to the quantum computer which are used to send direct current (DC) and/or radio frequency (RF) electrical signals to manipulate or monitor the qubits within the quantum computer that perform its computational tasks. The cryostat is filled with these coaxial cables, which are typically semi-rigid coaxial cables with small diameters and constructed of materials with low thermal conductivity (such as stainless steel) to minimize heat conduction from the outside environment to the quantum computer, which would cause it to heat up and disrupt its operation.

Most metals that are used for coaxial cable conductors follow the Weidman-Franz Law which states that the thermal conductivity and electrical conductivity of a material are closely related at a specific temperature, meaning that a material with low thermal conductivity at a certain temperature will also have low electrical conductivity. This means that coaxial cables made of low thermal conductivity materials will also have low electrical conductivity, causing the cable to have high signal attenuation rates, which get higher with longer cable lengths and higher frequencies being transmitted through the cable. Decreasing the diameter of the coaxial cable exacerbates this attenuation problem.

Superconductors such as niobium-titanium (NbTi) do not follow the Weidman-Franz Law when they are cooled down below their superconducting transition temperature. Below this temperature (around 9K for NbTi) superconductor materials become “ideal” electrical conductors with zero electrical resistance while retaining the typical values for their thermal conductivity at that temperature, which is typically very low for most superconductors at temperatures below 4 Kelvin. A coaxial cable with a superconducting center conductor is an ideal approach for transmitting DC or high frequency signals over long lengths and in very small diameters with very low attenuation rates.

When cooled below their superconducting transition temperature, superconductors also exhibit the Meissner Effect which is the expulsion of magnetic field. The outer conductor of coaxial cable is designed to “shield” the signal being transmitted down the center conductor from any electrical interference (magnetic fields). Traditional coaxial cables with outer conductors made of non-superconducting materials such as copper do this job well, but a small amount of interference will still permeate the outer conductor and affect the electrical signal being transmitted. A coaxial cable that uses a superconductor material for the outer conductor will reject any magnetic interference that comes near it while superconducting, making it an optimal interference “shield”.

The above reasons describe why superconducting coaxial cables are an ideal design approach for quantum computers at low temperature. Superconducting coaxial cables are currently only offered in a semi-rigid form where the outer conductor of the cable is constructed of a solid tube that is mechanically drawn (squeezed) onto the dielectric and center conductor. The metal tubing that is used for the outer conductor can only be manufactured in finite diameters (especially for NbTi) and mechanically drawing such small tubing becomes very difficult as diameters decrease. This limits the typical manufacturing process used to make semi-rigid cable in how small of cable diameter it can make.

Accordingly, it may be desired to provide a flexible superconducting micro-coaxial cable with a very small diameter for minimizing space and heat loads, and designed for use in quantum computing systems.

This background information is provided to reveal information believed by the applicant to be of possible relevance to the present invention. No admission is necessarily intended, nor should be construed, that any of the preceding information constitutes prior art against the present invention.

### SUMMARY OF THE EMBODIMENTS

An object of the present invention may be to provide a flexible superconducting micro-coaxial cable designed for use in quantum computing systems. The micro-coaxial cable includes an inner conductor made of a first superconductive material, surrounded by a dielectric layer. Circumferentially surrounding the dielectric layer is a braided outer conductor, made of a second superconductive material, providing more than 90% coverage.

Additionally, and/or alternatively, the first and second superconductive materials can be either type-I superconductors, such as Aluminum (Al), Lead (Pb), Titanium (Ti), Indium (In), and Tin (Sn), or type-II superconductors, including magnesium diboride (MgB2), niobium-titanium (NbTi), niobium-tin (Nb3Sn), and niobium-germanium (Nb3Ge).

Additionally, and/or alternatively, the braided outer conductor may include a foil layer to provide additional shielding.

Additionally, and/or alternatively, the inner conductor may have a specific diameter requirement, for example, 24 AWG or smaller.

Embodiments also include a method for making the flexible superconducting micro-coaxial cable. The method involves forming the inner conductor using the first superconductive material, followed by circumferentially surrounding it with a dielectric layer. Finally, the dielectric layer is surrounded by the braided outer conductor made of the second superconductive material.

Accordingly, the disclosed superconducting micro-coaxial cable presents a unique and efficient solution for use in quantum computing systems, enabling high-performance signal transmission with superconductive materials, enhanced shielding capabilities, and flexibility for diverse applications in advanced technologies.

### BRIEF DESCRIPTION OF THE DRAWINGS

The example embodiments are best understood from the following detailed description when read with the accompanying drawing figures. In fact, the dimensions may be arbitrarily increased or decreased for clarity of discussion. Wherever applicable and practical, like reference numerals refer to like elements.

FIG. 1 is a cross-sectional view illustrating an example embodiment of a flexible superconducting micro-coaxial cable in accordance with features of the present invention.

FIG. 2 is a perspective cut-away view illustrating details of a portion of the flexible superconducting micro-coaxial cable of FIG. 1.

FIG. 3 is another perspective view illustrating details of multiple flexible superconducting micro-coaxial cables of FIG. 1 and including connectors.

### DETAILED DESCRIPTION

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Those of ordinary skill in the art realize that the following descriptions of the embodiments of the present invention are illustrative and are not intended to be limiting in any way. Other embodiments of the present invention will readily suggest themselves to such skilled persons having the benefit of this disclosure. Like numbers refer to like elements throughout.

In this detailed description of the present invention, a person skilled in the art should note that directional terms, such as “above,” “below,” “upper,” “lower,” and other like terms are used for the convenience of the reader in reference to the drawings. Also, a person skilled in the art should notice this description may contain other terminology to convey position, orientation, and direction without departing from the principles of the present invention.

Furthermore, in this detailed description, a person skilled in the art should note that quantitative qualifying terms such as “generally,” “substantially,” “mostly,” and other terms are used, in general, to mean that the referred to object, characteristic, or quality constitutes a majority of the subject of the reference. The meaning of any of these terms is dependent upon the context within which it is used, and the meaning may be expressly modified.

A coaxial cable that uses a flexible braided outer conductor instead of a solid tube allows the use of manufacturing processes that are better suited for making coaxial cables with very small diameters. Braided outer conductors are constructed by weaving several tiny wires around the dielectric. This weaving process can be performed on much smaller diameters than a semi-rigid coaxial cable manufacturing method could use. A braided outer conductor also produces a coaxial cable that is flexible (instead of rigid), making it more user-friendly for installation and use.

A unique coaxial cable design for quantum computers is one where the cable conductors are made using superconductor materials with a braided outer conductor. The superconduction of the center conductor creates an ideal conductor for transmitting the high frequency signals needed to manipulate qubits in the quantum computer with very little attenuation regardless of cable length and diameter. The superconduction of the outer conductor exploits the Meissner Effect to shield the transmitted signal from outside magnetic interference better than any non-superconducting metal. The braided outer conductor gives the ability to make coaxial cable in very small diameters that will ultimately conduct less heat to the quantum computer and be more user-friendly. The smaller cable diameter will also take up less space, allowing for a higher density of coaxial cables to fit inside the cryostat to accommodate the growing number of qubits in future quantum computers.

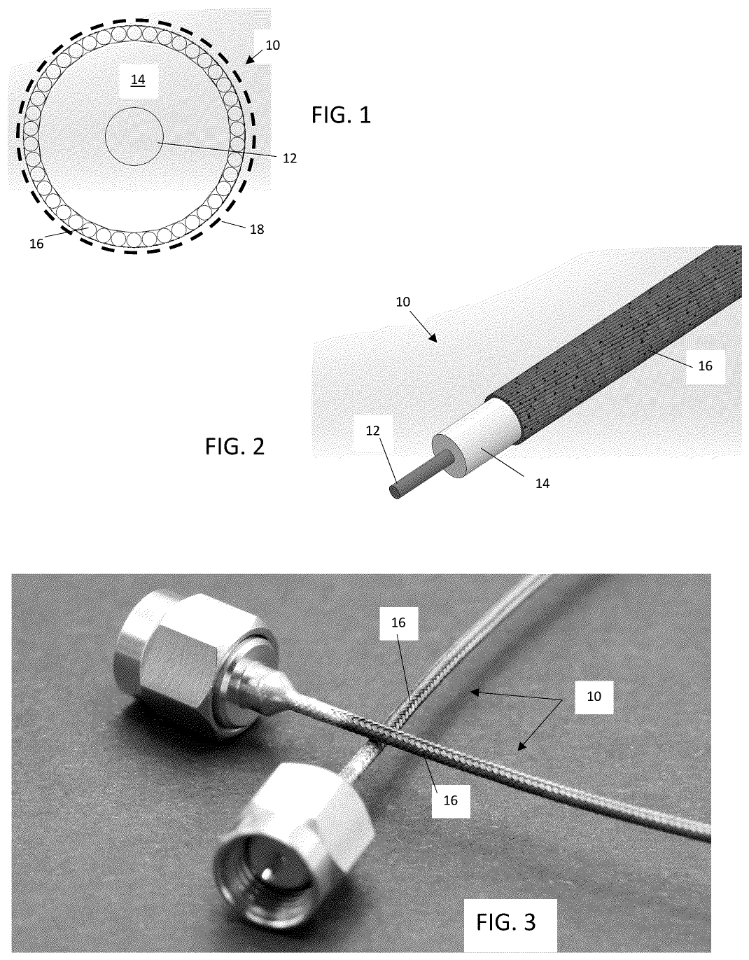

FIGS. 1-6 illustrate an example embodiment of a flexible superconducting micro-coaxial cable 10 configured for use in a quantum computing system. The micro-coaxial cable 10 includes an inner conductor 12 formed of a first superconductive material. The inner conductor 12 may have a specific diameter, for example, 24 AWG or smaller. The flexible superconducting micro-coaxial cable 10 may be formed in small diameters (e.g., 0.086″ and smaller).

A dielectric layer 14 circumferentially surrounds the inner conductor. The dielectric layer 14 may be PTFE (Teflon), FEP, PFA, PEEK, or polyimide in multiple thicknesses to accommodate characteristic impedances such as 750, 500, and smaller.

A braided outer conductor 16 circumferentially surrounds the dielectric layer 14 with more than 90% coverage. The braided outer conductor 16 is formed of a second superconductive material. For example, the criss-crossed braid pattern of the outer conductor 16 may be made using a braiding machine with eight to sixteen braid carriers. Each braid carrier holds a spool of ultra-fine wires (40 AWG diameter and smaller) with one to ten wires on each spool (number of wire ends). A braid density setting of five to seventy-five picks per inch (PPI) may be used to create a braid with 90% or better coverage. There may be a total of one to one hundred different wires used to create the braid, depending on the final diameter of the micro coaxial cable 10.

The first and second superconductive materials can be either type-I superconductors, such as Aluminum (AI), Lead (Pb), Titanium (Ti), Indium (In), and Tin (Sn), or type-II superconductors, including magnesium diboride (MgB2), niobium-titanium (NbTi), niobium-tin (Nb3Sn), and niobium-germanium (Nb3Ge).

Also, the braided outer conductor 16 may include a foil layer 18 to provide additional shielding.

Embodiments also include a method for making the flexible superconducting micro-coaxial cable 10. The method involves forming the inner conductor 12 using the first superconductive material, followed by circumferentially surrounding it with a dielectric layer 14. Finally, the dielectric layer 14 is surrounded by the braided outer conductor 16 made of the second superconductive material. The braided outer conductor 16 may further include a foil layer configured to provide additional shielding.

The micro coaxial cable 10 of the present embodiments will be used in the cryogenic high-vacuum environments of a cryostat or dilution refrigerator in application areas such as quantum computing as well as other low-temperature research near absolute zero. They carry DC and/or radio frequency electrical signals to electronic devices such as quantum computers held at temperatures near absolute zero. When the superconducting cable is cooled below its superconducting transition temperature, it becomes a nearly perfect electrical conductor providing little to no loss of signal performance.

An objective of the embodiments of the invention is to provide a micro coaxial cable 10 that is flexible for ease of use, having a very small diameter for minimizing space and heat loads, and made from a superconducting material which minimizes heat loads from its inherently low thermal conductivity while maximizing electrical signal integrity due to its superconducting behavior. The invention is a much smaller diameter cable that is flexible while still retaining the superconducting behavior of the superconducting semi-rigid coaxial cable 10.

The present invention may have also been described, at least in part, in terms of one or more embodiments. An embodiment of the present invention is used herein to illustrate the present invention, an aspect thereof, a feature thereof, a concept thereof, and/or an example thereof. A physical embodiment of an apparatus, an article of manufacture, a machine, and/or of a process that embodies the present invention may include one or more of the aspects, features, concepts, examples, etc. described with reference to one or more of the embodiments discussed herein. Further, from figure to figure, the embodiments may incorporate the same or similarly named functions, steps, modules, etc. that may use the same or different reference numbers and, as such, the functions, steps, modules, etc. may be the same or similar functions, steps, modules, etc. or different ones.

The above description provides specific details, such as material types and processing conditions to provide a thorough description of example embodiments. However, a person of ordinary skill in the art would understand that the embodiments may be practiced without using these specific details.

Some of the illustrative aspects of the present invention may be advantageous in solving the problems herein described and other problems not discussed which are discoverable by a skilled artisan. While the above description contains much specificity, these should not be construed as limitations on the scope of any embodiment, but as exemplifications of the presented embodiments thereof. Many other ramifications and variations are possible within the teachings of the various embodiments. While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best or only mode contemplated for carrying out this invention, but that the invention will include all embodiments falling within the scope of the appended claims. Also, in the drawings and the description, there have been disclosed exemplary embodiments of the invention and, although specific terms may have been employed, they are unless otherwise stated used in a generic and descriptive sense only and not for purposes of limitation, the scope of the invention therefore not being so limited. Moreover, the use of the terms first, second, etc. do not denote any order or importance, but rather the terms first, second, etc. are used to distinguish one element from another. Furthermore, the use of the terms a, an, etc. do not denote a limitation of quantity, but rather denote the presence of at least one of the referenced item. Thus, the scope of the invention should be determined by the appended claims and their legal equivalents, and not by the examples given.

1. A flexible superconducting micro-coaxial cable configured for use in a quantum computing system, the micro-coaxial cable comprising:
an inner conductor formed of a first superconductive material;
a dielectric layer circumferentially surrounding the inner conductor; and
a braided outer conductor circumferentially surrounding the dielectric layer with more than 90% coverage and formed of a second superconductive material.

2. The micro-coaxial cable according to claim 1, wherein the first superconductive material comprises a type-I superconductor.

3. The micro-coaxial cable according to claim 2, wherein the type-I superconductor comprises at least one of Aluminum (Al), Lead (Pb), Titanium (Ti), Indium (In), and Tin (Sn).

4. The micro-coaxial cable according to claim 1, wherein the second superconductive material comprises a type-I superconductor.

5. The micro-coaxial cable according to claim 4, wherein the type-I superconductor comprises at least one of Aluminum (Al), Lead (Pb), Titanium (Ti), Indium (In), and Tin (Sn).

6. The micro-coaxial cable according to claim 1, wherein the first superconductive material comprises a type-II superconductor.

7. The micro-coaxial cable according to claim 6, wherein the type-II superconductor comprises at least one of magnesium diboride (MgB2), niobium-titanium (NbTi), niobium-tin (Nb3Sn), and niobium-germanium (Nb3Ge).

8. The micro-coaxial cable according to claim 1, wherein the second superconductive material comprises a type-II superconductor.

9. The micro-coaxial cable according to claim 8, wherein the type-II superconductor comprises at least one of magnesium diboride (MgB2), niobium-titanium (NbTi), niobium-tin (Nb3Sn), and niobium-germanium (Nb3Ge).

10. The micro-coaxial cable according to claim 1, wherein the braided outer conductor further comprises a foil layer configured to provide additional shielding.

11. A flexible superconducting micro-coaxial cable configured for use in a quantum computing system, the micro-coaxial cable comprising:
an inner conductor formed of a first superconductive material with a diameter of 24 AWG or smaller;
a dielectric layer circumferentially surrounding the inner conductor; and
a braided outer conductor circumferentially surrounding the dielectric layer with more than 90% coverage and formed of a second superconductive material.

12. The micro-coaxial cable according to claim 11, wherein the first superconductive material comprises at least one of magnesium diboride (MgB2), niobium-titanium (NbTi), niobium-tin (Nb3Sn), and niobium-germanium (Nb3Ge).

13. The micro-coaxial cable according to claim 11, wherein the second superconductive material comprises at least one of magnesium diboride (MgB2), niobium-titanium (NbTi), niobium-tin (Nb3Sn), and niobium-germanium (Nb3Ge).

14. The micro-coaxial cable according to claim 11, wherein the braided outer conductor further comprises a foil layer configured to provide additional shielding.

15. A method of making a flexible superconducting micro-coaxial cable configured for use in a quantum computing system, the method comprising:
forming an inner conductor of a first superconductive material;
circumferentially surrounding the inner conductor with a dielectric layer; and
circumferentially surrounding the dielectric layer with a braided outer conductor having more than 90% coverage and formed of a second superconductive material.

16. The method according to claim 15, wherein the first superconductive material comprises a type-I superconductor comprising at least one of Aluminum (Al), Lead (Pb), Titanium (Ti), Indium (In), and Tin (Sn).

17. The method according to claim 15, wherein the second superconductive material comprises a type-I superconductor comprising at least one of Aluminum (Al), Lead (Pb), Titanium (Ti), Indium (In), and Tin (Sn).

18. The method according to claim 15, wherein the first superconductive material comprises a type-II superconductor comprising at least one of magnesium diboride (MgB2), niobium-titanium (NbTi), niobium-tin (Nb3Sn), and niobium-germanium (Nb3Ge).

19. The method according to claim 15, wherein the second superconductive material comprises a type-II superconductor comprising at least one of magnesium diboride (MgB2), niobium-titanium (NbTi), niobium-tin (Nb3Sn), and niobium-germanium (Nb3Ge).

20. The method according to claim 15, wherein the braided outer conductor further comprises a foil layer configured to provide additional shielding.
